(19) United States
(12) Patent Application Publication
(10) Pub. No.: US 2014/0339504 A1
(43) Pub. Date: Nov. 20, 2014

(54) MAGNETIC MEMORY DEVICE AND METHOD OF MANUFACTURING THE SAME

(71) Applicants: KYOUNGSUN KIM, Hwaseong-si (KR); WOOJIN KIM, Yongin-si (KR); WOO CHANG LIM, Seoul (KR)

(72) Inventors: KYOUNGSUN KIM, Hwaseong-si (KR); WOOJIN KIM, Yongin-si (KR); WOO CHANG LIM, Seoul (KR)

(21) Appl. No.: 14/264,017

(22) Filed: Apr. 28, 2014

(30) Foreign Application Priority Data
May 15, 2013 (KR) 10-2013-0055179

(51) Int. Cl. H01L 43/12; H01L 43/02

(52) U.S. Cl. CPC H01L 43/12; H01L 43/02
USPC 257/16; 438/3

(57) ABSTRACT

A magnetic memory device and method of manufacturing the same are provided. The magnetic memory device can include a first vertical magnetic pattern on a substrate, a second vertical magnetic pattern on the first vertical magnetic pattern, and a tunnel barrier pattern disposed between the first vertical magnetic pattern and the second vertical magnetic pattern. The first vertical magnetic pattern can include a first pattern on the substrate, a second pattern on the first pattern, and an exchange coupling pattern between the first pattern and the second pattern. The first pattern can comprise an amorphous magnetic substance and a component comprising at least one of platinum, palladium, and nickel.

### CROSS-REFERENCE TO RELATED APPLICATIONS

This U.S. non-provisional patent application claims priority under 35 U.S.C. §119 of Korean Patent Application No. 10-2013-0055179, filed on May 15, 2013, the contents of which are hereby incorporated herein by reference in its entirety.

### BACKGROUND

The present disclosure relates to a semiconductor device and a method of manufacturing the same, and more particularly, to a magnetic memory device and a method of manufacturing the same in which surface roughness of the magnetic layers can be reduced.

Electrical equipment is increasingly demanding higher speeds and lower power consumption. Accordingly, the need for a high speed semiconductor device that operates at a low operating voltage is also increasing. In order to meet these needs, a magnetic memory device has been proposed as a semiconductor memory device. Since magnetic memory devices offer high-speed operation with non-volatile characteristics, these devices are being considered for providing next-generation semiconductor memory devices.

In general, a magnetic memory device may include a magnetic tunnel junction (MTJ) pattern. The MTJ pattern may include two magnetic substances and an insulating layer disposed therebetween. The resistance of the MTJ pattern may vary depending on the magnetization direction of the two magnetic substances. For example, if the magnetization direction of the two magnetic substances is anti-parallel, the MTJ pattern may have a high resistance, and if the magnetization direction of the two magnetic substances is parallel, the MTJ pattern may have a low resistance. It is therefore possible to use the difference between these resistances to store a data value in the magnetic memory device.

### SUMMARY

According to the present inventive concepts, a magnetic memory device is provided having excellent reliability by improving its switching failure and breakdown voltage (BV) characteristics. A method of manufacturing the same is also provided.

According to one embodiment of the inventive concepts, a magnetic memory device includes a first vertical magnetic pattern disposed on a substrate. A second vertical magnetic pattern is arranged on the first vertical magnetic pattern; and a tunnel barrier pattern is arranged between the first vertical magnetic pattern and the second vertical magnetic pattern. The first vertical magnetic pattern can include a first pattern disposed on the substrate; a second pattern arranged on the first pattern; and an exchange coupling pattern arranged between the first pattern and the second pattern. The first pattern can comprise an amorphous magnetic substance and a component X, wherein the component X can include at least one of platinum, palladium, and nickel.

In some embodiments, the first pattern may have a super lattice structure that is formed by alternately stacking the amorphous magnetic substance and the component X.

In some embodiments, the amorphous magnetic substance may include at least one of CoB, FeB, CoFeB, CoFeBTa, CoFeSiB, FeZr, and CoHf.

In some embodiments, the magnetic memory device may further include a seed pattern arranged between the substrate and the first pattern, wherein a lower surface of the first pattern is in contact with an upper surface of the seed pattern.

In some embodiments, the seed pattern may include ruthenium (Ru).

In some embodiments, the first pattern may include a plurality of first sub patterns containing the amorphous magnetic substance; and a plurality of second sub patterns containing the component X, wherein the first pattern has a multi-layered structure in which the first sub patterns and the second sub patterns are alternately stacked.

In some embodiments, the magnetic memory device may include a seed pattern arranged between the substrate and the first pattern. A lower surface of a lowest layer of the first sub patterns may be in contact with an upper surface of the seed pattern.

In some embodiments, a thickness of each of the second sub patterns may be thicker than a thickness of each of the first sub patterns.

In some embodiments, the first vertical magnetic pattern may be a pinned layer having a magnetization direction that is fixed.

In some embodiments, the first pattern may have a magnetization direction that is perpendicular to an upper surface of the substrate and is uni-directionally fixed, and the second pattern may have a magnetization direction that is perpendicular to an upper surface of the substrate and is fixed to be anti-parallel to the magnetization direction of the first pattern.

In some embodiments, the second vertical magnetic pattern may be a free layer having a magnetization direction that varies.

According to another aspect of the inventive concepts, a method of manufacturing a magnetic memory device includes forming a seed layer on a substrate and then alternately and repetitively depositing an amorphous magnetic substance and a component X on the seed layer to form a first layer. The component X can, for example, comprise at least one of platinum, palladium, and nickel. An exchange coupling layer is then formed on the first layer; and a second layer is formed on the exchange coupling layer. The second layer, the exchange coupling layer, the first layer, and the seed layer are then successively patterned to form a seed pattern, a first pattern, an exchange coupling pattern, and a second pattern that are sequentially stacked on the substrate.

In some embodiments, the amorphous magnetic substance may include at least one of CoB, FeB, CoFeB, CoFeBTa, CoFeSiB, FeZr, and CoHf.

In some embodiments, the first pattern may have a magnetization direction that is perpendicular to an upper surface of the substrate and that is uni-directionally fixed, and the second pattern may have a magnetization direction that is perpendicular to an upper surface of the substrate and that is fixed to be anti-parallel to the magnetization direction of the first pattern.

In some embodiments, the first layer may be formed as a super lattice in which the amorphous magnetic substance and the component X are alternately stacked. Depositing the amorphous magnetic substance and the component X may be performed at a temperature of between about 300° C. to about 350° C. using a high-temperature sputtering process.

### BRIEF DESCRIPTION OF THE DRAWINGS

The accompanying drawings are included to provide a further understanding of the inventive concepts, and are incorporated in and constitute a part of this specification. The drawings illustrate exemplary embodiments of the inventive concepts and, together with the description, serve to explain principles of the inventive concepts. In the drawings:

FIG. 1 is a schematic circuit diagram of a unit memory cell of a magnetic memory device according to an embodiment of the inventive concepts;

FIG. 2 is a schematic cross-sectional view of a magnetic memory device according to an embodiment of the inventive concepts;

FIGS. 3 to 5 are schematic cross-sectional views of a partially constructed magnetic memory device, illustrating a method of manufacturing a magnetic memory device according to an embodiment of the inventive concepts;

FIG. 6 is a schematic cross-sectional view of a magnetic memory device according to another embodiment of the inventive concepts;

FIGS. 7 and 8 are schematic cross-sectional views of a partially constructed magnetic memory device illustrating a method of manufacturing a magnetic memory device according to another embodiment of the inventive concepts; and

FIGS. 9 and 10 are schematic block diagrams illustrating electronic devices including a semiconductor device according to embodiments of the inventive concepts.

### DETAILED DESCRIPTION

In order to help readers fully understand the configuration and effects of the inventive concepts, exemplary embodiments of the inventive concepts will be described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will be understood that when a component is referred to as being “on” another component, it can be directly on the another component or intervening components may also be present therebetween. In the drawings, the thickness of components is exaggerated for effective description of technical content. Like reference numerals refer to like components throughout the specification.

Embodiments in the specification will be described with cross-sectional views and/or plane views as idealized exemplary views of the present invention. In the drawings, the thickness of layers and regions may be exaggerated for clarity. Thus, regions exemplified in the drawings have general properties, and are not used to illustrate a specific shape of a device region. The shapes and sizes of features shown in the drawings should therefore not be construed as limiting the scope of the present inventive concepts. Though terms like “first,” “second,” and “third” are used to describe various regions and layers in various embodiments of the present inventive concepts, the regions and the layers are not limited by these terms. For instance, a layer termed “first” in one embodiment may be a “second” or “third” layer in another embodiment, and vice-versa. Embodiments described and exemplified herein include complementary embodiments thereof.

The terms used in the specification do not limit the inventive concepts but are used to describe embodiments thereof. Terms in singular form may include plural forms as well unless specifically stated otherwise. The terms “include,” “comprise,” “including,” or “comprising,” specifies a property, a region, a fixed number, a step, a process, an element and/or a component but does not exclude the presence of other properties, regions, fixed numbers, steps, processes, elements and/or components.

The principles of the inventive concepts will be described in detail below with respect to various exemplary embodiments thereof.

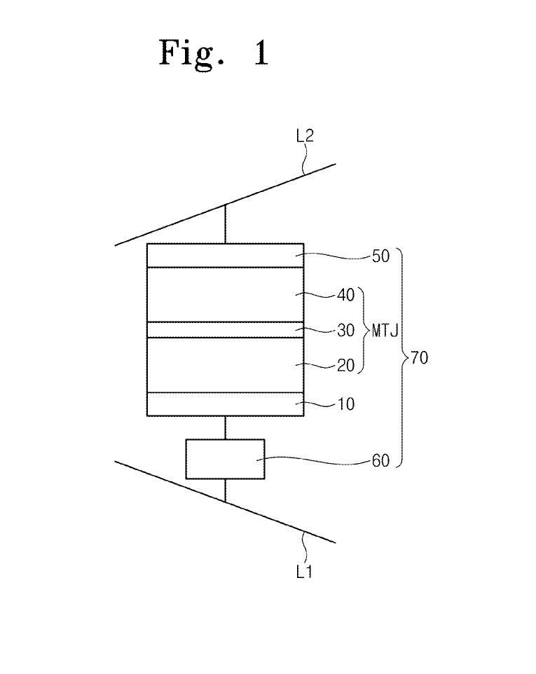

FIG. 1 is a schematic circuit diagram of a unit memory cell of a magnetic memory device according to embodiments of the inventive concepts.

Referring to FIG. 1, a unit memory cell 70 may connect a first wiring L1 and a second wiring L2 that cross each other. The unit memory cell 70 may include a switching element 60, a magnetic tunnel junction (MTJ), a first conductive structure 10, and a second conductive structure 50. The switching element 60, the first conductive structure 10, the MTJ, and the second conductive structure 52 may be electrically connected in serial. One of the first and second wirings L1 and L2 may be used as a word line and the other may be used as a bit line.

The switching element 60 may be configured to selectively control the flow of an electric charge that passes through the MTJ. For example, the switching element 60 may be one of a diode, a PNP bipolar transistor, an NPN bipolar transistor, an NMOS field effect transistor (FET), and a PMOS FET. If the switching element 60 is configured using a MOSFET or a bipolar transistor that is a three-terminal element, an additional wiring (not shown) may be connected to the switching element 60.

The MTJ may include a first magnetic structure 20 and a second magnetic structure 40, with a tunnel barrier 30 arranged therebetween. Each of the first and second magnetic structures 20 and 40 may include at least one magnetic layer that is formed of a magnetic material. The first conductive structure 10 may be placed between the first magnetic substructure 20 and the switching element 60, and the second conductive substructure 50 may be placed between the second magnetic substructure 40 and the second wiring L2.

The magnetization direction of a magnetic layer of either the first magnetic structure 20 or the second magnetic structure 40 may be fixed, irrespective of an external magnetic field applied under a typical usage environment. A magnetic layer having this fixed magnetization characteristic may be defined as a pinned layer. Meanwhile, the magnetization direction of the magnetic layer of the other magnetic substructure 20 or 40 may be switched by application of an external magnetic field thereto. A magnetic layer having a variable magnetic characteristic may be defined as a free layer. The MTJ may include at least one free layer and at least one pinned layer that are separated by a tunnel barrier 30.

The electrical resistance of the MTJ may depend on the relative magnetization directions of the free layer and the pinned layer. For example, the electrical resistance of the MTJ may be much greater in a case where the magnetization directions of the free layer and the pinned layer are anti-parallel to each other than in a case where they are parallel to each other. As a result, the electrical resistance of the MTJ may be regulated by changing the magnetization direction of the free layer, and the MTJ may therefore be used as a data storage element in a magnetic memory device according to the inventive concepts.

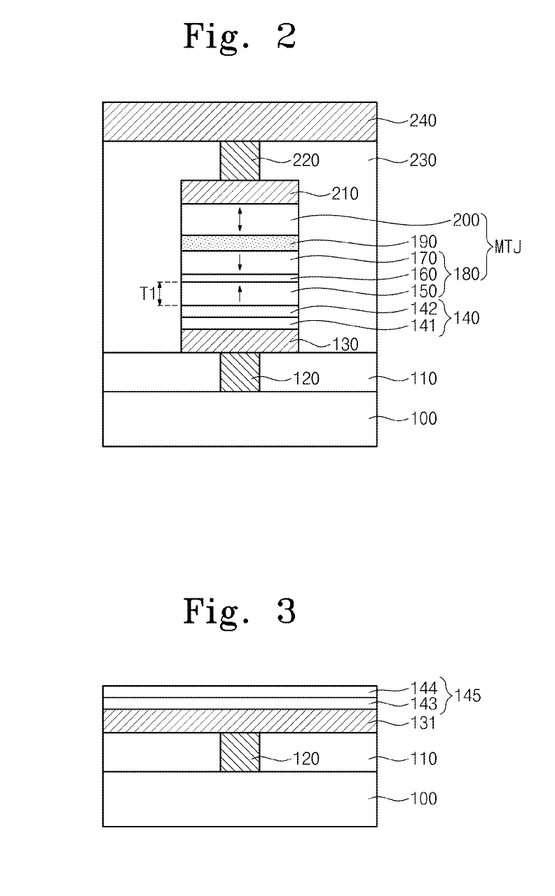

FIG. 2 is a schematic cross-sectional view of a magnetic memory device according to an embodiment of the inventive concepts.

Referring to FIG. 2, a first dielectric layer 110 may be arranged on a substrate 100 and a lower contact plug 120 may pass through the first dielectric layer 110. A lower surface of the lower contact plug 120 may be electrically connected to one terminal of the switching element. The substrate 100 may be comprised of one or more materials having semiconductor characteristics, insulating materials, conductors, or semiconductors that are covered with insulating materials. As an example, the substrate 100 may be a silicon wafer. The first dielectric layer 110 may include an oxide, nitride, and/or an oxynitride. The lower contact plug 120 may include a conductive material. As an example, the conductive material may be at least one of a dopant-doped semiconductor (e.g., doped silicon, doped germanium, doped silicon-germanium, etc.), metal (e.g., titanium, tantalum, tungsten, etc.), and a conductive metal nitride (e.g., titanium nitride, tantalum nitride, etc.).

A first conductive pattern 130, a seed pattern 140, a first vertical magnetic pattern 180, a tunnel barrier pattern 190, a second vertical magnetic pattern 200, and a second conductive pattern 210 may be sequentially stacked on the first dielectric layer 110. The first conductive pattern 130 may be electrically connected to an upper surface of the lower contact plug 120. The first vertical magnetic pattern 180, the tunnel barrier pattern 190, and the second vertical magnetic pattern 200 may be included in the MTJ. The first conductive pattern 130, the seed pattern 140, the MTJ, and the second conductive pattern 210 may have sidewalls that are aligned with each other.

The first vertical magnetic pattern 180 may include a first pattern 150 disposed on the seed pattern 140, a second pattern 170 arranged on the first pattern 150, and an exchange coupling pattern 160 disposed between the first pattern 150 and the second pattern 170. In particular, the first pattern 150 may be arranged between the seed pattern 140 and the exchange coupling pattern 160, and the second pattern 170 may be arranged between the exchange coupling pattern 160 and the tunnel barrier pattern 190.

The first vertical magnetic pattern 180 may have a magnetization direction which is substantially perpendicular to the upper surface of the substrate 100. Likewise, a magnetization direction of the second vertical magnetic pattern 200 may also be substantially perpendicular to the upper surface of the substrate 100.

According to an embodiment, the first vertical magnetic pattern 180 may be a pinned layer having a fixed magnetization direction, and the second vertical magnetic pattern 200 may be a free layer having a variable magnetization direction. More particularly, the first pattern 150 may have an easy axis that is substantially perpendicular to the upper surface of the substrate 100. Thus, the first pattern 150 may have a magnetization direction that is substantially perpendicular to the upper surface of the substrate 100. The magnetization direction of the first pattern 150 may be fixed in one direction. Likewise, the second pattern 170 may also have an easy axis that is substantially perpendicular to the upper surface of the substrate 100. Thus, the second pattern 170 may have a magnetization direction that is substantially perpendicular to the upper surface of the substrate 100. The magnetization direction of the second pattern 170 may be fixed to be anti-parallel to the magnetization direction of the first pattern 150 by the exchange coupling pattern 160. Through a program operation, the magnetization direction of the second vertical magnetic pattern 200 may be set to be parallel to or anti-parallel to the magnetization direction of the second pattern 170.

The first conductive pattern 130 may include a conductive material. As an example, the conductive material may be a conductive metal nitride such as titanium nitride and/or tantalum nitride. The first conductive pattern 130 may be arranged under the MTJ to function as a lower electrode. The seed pattern 140 may include a first sub pattern 141 and a second sub pattern 142 that are sequentially stacked. As an example, the first sub pattern 141 may include tantalum (Ta) and the second sub pattern 142 may include ruthenium (Ru). The seed pattern 140 may perform a seed function that assists the first pattern 150 in growing.

The first pattern 150 may include an amorphous magnetic substance and a component X. The component X may include at least one of platinum (Pt), palladium (Pd), and nickel (Ni). The amorphous magnetic substance may include at least one of CoB, FeB, CoFeB, CoFeBTa, CoFeSiB, FeZr, and CoHf, for example. The first pattern 150 may have a super lattice structure in which the amorphous magnetic substance and the component X are alternately stacked. As an example, the first pattern 150 may be a super lattice structure in which cobalt-boron (CoB) and platinum (Pt) are alternately stacked, and the super lattice structure may have a crystalline structure similar to that of L11. Here, L11 is a crystalline structure by strukturbericht designation, and the crystalline structure similar to that of L11 means a crystalline structure in which an amorphous material is included in the L11 structure. The first pattern 150 may have a first thickness T1.

The seed pattern 140 may be in contact with the first pattern 150 and thus may affect the growth of the crystal of the first pattern 150. A surface roughness of the seed pattern 140 may spread to the first pattern 150 and other patterns that are formed on the first pattern 150. More particularly, the surface roughness of the seed pattern 140 may be transited to the first vertical magnetic pattern 180 through the first pattern 150. If the crystal axis of the crystal structure of a material (e.g., ruthenium (Ru)) that is included in the seed pattern 140 is misaligned, the surface roughness of the seed pattern 140 may increase and thus the surface roughness of the first pattern 150 and the surface roughness of the first vertical magnetic pattern 180 (namely, the interface between the first vertical magnetic pattern 180 and the tunnel barrier pattern 190) may also increase. If the surface roughness of the first pattern 150 increases, the dispersion of the coercive force Hc of the first pattern 150 also increases, and the magnetic memory device may experience switching failure. Moreover, if the surface roughness of the first vertical magnetic pattern 180 increases, the surface roughness of the tunnel barrier pattern 190 on the first vertical magnetic pattern 180 may also increase. As the surface roughness of the tunnel barrier pattern 190 increases, the Breakdown Voltage (BV) characteristic decreases and the reliability of the magnetic memory device may decrease.

According to the inventive concepts, since the first pattern 150 includes an amorphous magnetic substance, the surface roughness of the seed pattern 140 may not significantly affect the first pattern 150. In particular, a surface roughness of an amorphous material may be smaller than that of a crystalline material. Thus, since the first pattern 150 includes an amorphous magnetic material, it may keep the surface roughness of the seed pattern 140 (including the above-described crystalline materials such as tantalum, ruthenium, etc.) from becoming transited to the first pattern 150, the first vertical magnetic pattern 180, and the tunnel barrier pattern 190. As the surface roughness of the first pattern 150 decreases, the dispersion of the coercive force Hc of the first pattern 150 decreases, and thus the switching failure characteristics of the magnetic memory device may be improved. Moreover, as the surface roughness of the tunnel barrier pattern 190 decreases, the BV characteristic is improved and thus a magnetic memory device having excellent reliability may be provided.

The exchange coupling pattern 160 may include at least one of ruthenium, iridium, and rhodium. The exchange coupling pattern 160 may antiferromagnetically couple the first pattern 150 to the second pattern 170. Due to the exchange coupling pattern 160, the second pattern 170 may have a magnetization direction that is anti-parallel to the magnetization direction of the first pattern 150.

The second pattern 170 may, for example, include at least one of cobalt iron boron (CoFeB), cobalt iron terbium (CoFeTb) in which terbium (Tb) occupies 10% or more, cobalt iron gadolinium (CoFeGd) in which gadolinium (Gd) occupies 10% or more, FePt of an L10 structure, FePd of an L10 structure, CoPd of an L10 structure, CoPt of an L10 structure, and CoPt of a hexagonal close packed lattice (HCP) structure. Alternatively, although not shown, the second pattern 170 may have a structure in which magnetic layers and non-magnetic layers are alternately and repeatedly stacked. The structure in which the magnetic layers and the non-magnetic layers are alternately and repeatedly stacked may be a structure of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n represents the number of times the layers are stacked).

The tunnel barrier pattern 190 may be formed of a dielectric material. For example, the tunnel barrier pattern 190 may be formed of magnesium oxide (MgO) and/or aluminum oxide (AlO).

The second vertical magnetic pattern 200 may, for instance, include at least one of cobalt iron boron (CoFeB), cobalt iron terbium (CoFeTb) in which terbium (Tb) occupies 10% or more, cobalt iron gadolinium (CoFeGd) in which gadolinium (Gd) occupies 10% or more, cobalt iron dysprosium (CoFeDy), FePt of an L10 structure, FePd of an L10 structure, CoPd of an L10 structure, CoPt of an L10 structure, and CoPt of a hexagonal close packed lattice (HCP) structure. Alternatively, although not shown, the second vertical magnetic pattern 200 may have a structure in which magnetic layers and non-magnetic layers are alternately and repeatedly stacked. The structure in which the magnetic layers and the non-magnetic layers are alternately and repeatedly stacked may be a structure of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n represents the number of stacked structures). A thickness of the second vertical magnetic pattern 200 may be thinner than that of the first vertical magnetic pattern 180. Alternatively, the coercive force of the second vertical magnetic pattern 200 may be smaller than that of the first vertical magnetic pattern 180. That is, according to some embodiments, the first vertical magnetic pattern 180 may correspond to a pinned layer and the second vertical magnetic pattern 200 may correspond to a free layer.

The second conductive pattern 210 may include a conductive material. As an example, the conductive material may be conductive metal nitride such as titanium nitride and/or tantalum nitride. The second conductive pattern 210 is arranged on the MTJ to function as an upper electrode.

A second dielectric layer 230 is arranged on an upper surface of the substrate 100 to cover the first conductive pattern 130, the seed pattern 140, the MTJ, and the second conductive pattern 210. The upper contact plug 220 may be connected to the second conductive pattern 210 through the second dielectric layer 230. The second dielectric layer 230 may include oxide, nitride and/or oxynitride, and the upper contact plug 220 may include at least one of a metal (e.g., titanium, tantalum, copper, aluminum, tungsten, etc.) and/or a conductive metal nitride (e.g., titanium nitride, tantalum nitride, etc.) A wiring 240 may be arranged on the second dielectric layer 230. The wiring 240 may be connected to the upper contact plug 220. The wiring 240 may include at least one of a metal (e.g., titanium, tantalum, copper, aluminum, tungsten, etc.) and/or a conductive metal nitride (e.g., titanium nitride, tantalum nitride, etc.). According to an embodiment, the wiring 240 may be a bit line.

Referring to FIGS. 1 and 2, the lower contact plug 120, the first conductive pattern 130, and the seed pattern 140 may correspond to the first conductive structure 10 and the second conductive pattern 210 and the upper contact plug 220 may correspond to the second conductive structure 50 of FIG. 1.

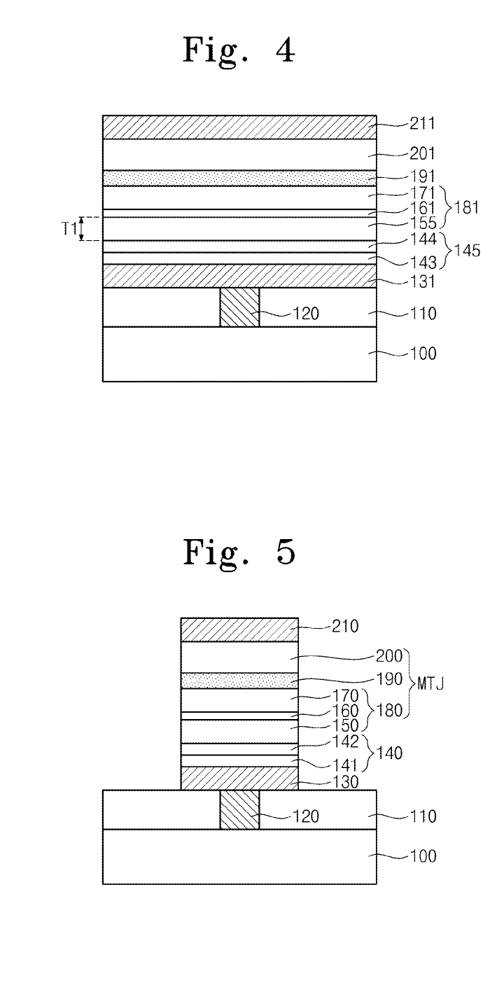

FIGS. 3 to 5 are schematic cross-sectional views of a partially constructed magnetic memory device for explaining a method of manufacturing a magnetic memory device according to an embodiment of the inventive concepts.

Referring to FIG. 3, the first dielectric layer 110 may be formed on the substrate 100, and the lower contact plug 120 may be formed passing through the first dielectric layer 110. The lower contact plug 120 may be electrically connected to one terminal of the switching element. The first conductive layer 131 may be formed on the first dielectric layer 110. The first conductive layer 131 may include a conductive material. As an example, the conductive material may be a conductive metal nitride such as titanium nitride and/or tantalum nitride. The first conductive layer 131 may be formed using a sputtering, chemical vapor deposition, or atomic layer deposition process. The seed layer 145 may be formed on the first conductive layer 131. The seed layer 145 may include a first sub layer 143 and a second sub layer 144 that are sequentially stacked. As an example, the first sub layer 143 may include tantalum (Ta) and the second sub layer 144 may include ruthenium Ru. The seed layer 145 may be formed using a sputtering, chemical vapor deposition, or atomic layer deposition process.

Referring to FIG. 4, a first vertical magnetic layer 181 may be formed on the seed layer 145. The first vertical magnetic layer 181 may include a first layer 155, an exchange coupling layer 161, and a second layer 171. The first layer 155 may be formed first on the seed layer 145. The first layer 155 may include an amorphous magnetic substance and a component X, which may be at least one of platinum (Pt), palladium (Pd), and nickel (Ni). The amorphous magnetic substance may, for example, include at least one of CoB, FeB, CoFeB, CoFeBTa, CoFeSiB, FeZr, and CoHf. The first layer 155 may be formed as a super lattice structure in which the amorphous magnetic substance and the component X are alternately stacked. As an example, the first layer 155 may be formed as a super lattice structure in which cobalt-boron (CoB) having a thickness of about 1.7 Å to about 2.7 Å and platinum (Pt) having a thickness of about 2 Å are alternately stacked, and the deposition process may be performed at between about 300° C. to about 350° C. using a high temperature sputtering process. The first layer 155 may be formed to have a thickness T1.

An exchange coupling layer 161 may be formed on the first layer 155. The exchange coupling layer 161 may include at least one of ruthenium, iridium, and rhodium. The exchange coupling layer 161 may be formed using a sputtering process, for example. The second layer 171 may be formed on the exchange coupling layer 161. As an example, the second layer 171 may include at least one of cobalt iron boron (CoFeB), cobalt iron terbium (CoFeTb) in which terbium (Tb) occupies 10% or more, cobalt iron gadolinium (CoFeGd) in which gadolinium (Gd) occupies 10% or more, cobalt iron dysprosium (CoFeDy), FePt of an L10 structure, FePd of an L10 structure, CoPd of an L10 structure, CoPt of an L10 structure, and CoPt of a hexagonal close packed lattice (HCP) structure.

Alternatively, although not shown, the second layer 171 may be formed by alternately and repeatedly stacking magnetic layers and non-magnetic layers. The structure in which the magnetic layers and the non-magnetic layers are alternately and repeatedly stacked may be a structure of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n represents how many times the layers are stacked). The second layer 171 may be formed using a sputtering process, for example.

A tunnel barrier layer 191 may be formed on the first vertical magnetic layer 181. The tunnel barrier layer 191 may be formed of a dielectric material (e.g., magnesium oxide and/or aluminum oxide). The tunnel barrier layer may be formed using a sputtering, chemical vapor deposition, or atomic layer deposition process. A second vertical magnetic layer 201 may be formed on the tunnel barrier layer 191. As an example, the second vertical magnetic layer 201 may include at least one of cobalt iron boron (CoFeB), cobalt iron terbium (CoFeTb) in which terbium (Tb) occupies 10% or more, cobalt iron gadolinium (CoFeGd) in which gadolinium (Gd) occupies 10% or more, cobalt iron dysprosium (CoFeDy), FePt of an L10 structure, FePd of an L10 structure, CoPd of an L10 structure, CoPt of an L10 structure, and CoPt of a hexagonal close packed lattice (HCP) structure.

Alternatively, although not shown, the second vertical magnetic layer 201 may be formed by alternately and repeatedly stacking magnetic layers and non-magnetic layers. As an example, the structure in which the magnetic layers and the non-magnetic layers are alternately and repeatedly stacked may be a structure of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n represents the number of stacked structures). The second vertical magnetic layer 201 may be formed using a sputtering, chemical vapor, atomic layer deposition, or epitaxial process. The second vertical magnetic layer 201 may be formed to be thinner than the first vertical magnetic layer 181. A second conductive layer 211 may be formed on the second vertical magnetic layer 201. The second conductive layer 211 may include conductive metal nitride and may be formed using a sputtering, chemical vapor deposition or atomic layer deposition process.

Referring to FIG. 5, the second conductive layer 211, the second vertical magnetic layer 201, the tunnel barrier layer 191, the first vertical magnetic layer 181, the seed layer 145, and the first conductive layer 131 may be successively patterned. Thus, a first conductive pattern 130, a seed pattern 140, a first vertical magnetic pattern 180, a tunnel barrier pattern 190, a second vertical magnetic pattern 200, and a second conductive pattern 210 that are sequentially stacked may be formed. The seed pattern 140 may include sequentially stacked first and second sub patterns 141 and 142, and the first vertical magnetic pattern 180 may include the sequentially stacked a first pattern 150, an exchange coupling pattern 160, and a second pattern 170.

Referring back to FIG. 2, a second dielectric layer 230 and an upper contact plug 220 passing through the second dielectric layer 230 may be formed on the upper surface of the substrate 100. The upper contact plug 220 may be formed to be electrically connected to the second conductive pattern 210. Subsequently, a wiring 240 that is connected to the upper contact plug 220 may be formed on the second dielectric layer 230. Accordingly, a magnetic memory device according to an embodiment of the inventive concepts may be formed using the above-described process.

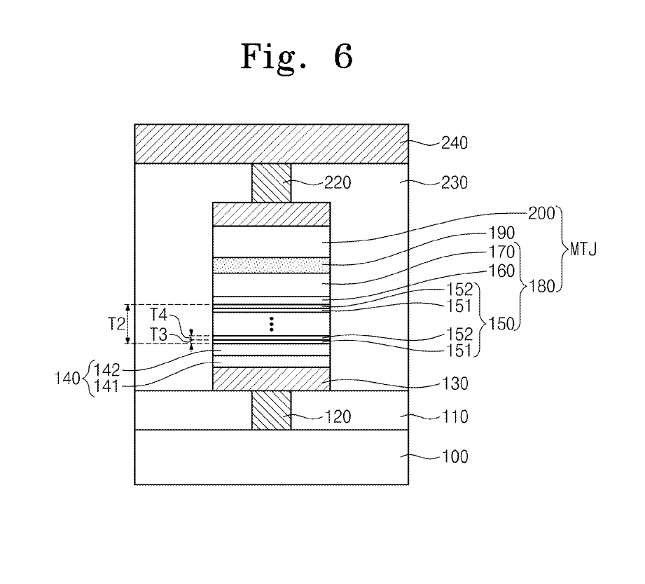

FIG. 6 is a cross-sectional view of a magnetic memory device according to another embodiment of the inventive concepts. The same reference numerals are used to designate like elements as in FIG. 2, and repeated descriptions thereof may be omitted for simplicity of description.

Referring to FIG. 6, the first vertical magnetic pattern 180 may include the first pattern 150 formed on the seed pattern 140, the second pattern 170 arranged on the first pattern 150, and the exchange coupling pattern 160 disposed between the first pattern 150 and the second pattern 170. In particular, the first pattern 150 may be arranged between the seed pattern 140 and the exchange coupling pattern 160, and the second pattern 170 may be arranged between the exchange coupling pattern 160 and the tunnel barrier pattern 190.

The first pattern 150 may include third sub patterns 151 and fourth sub patterns 152 that are stacked alternately and repeatedly. That is, the first pattern 150 may be a multi-layered structure in which the third and fourth patterns 151 and 152 are repeatedly stacked. The third sub patterns 151 may include an amorphous magnetic substance. The amorphous magnetic substance may include at least one of CoB, FeB, CoFeB, CoFeBTa, CoFeSiB, FeZr, and CoHf, for example. The fourth sub patterns 152 may include a component X, which may be at least one of platinum (Pt), palladium (Pd), and nickel (Ni). As an example, the third sub patterns 151 may include cobalt-boron (CoB) and the fourth sub patterns 152 may include platinum (Pt). A thickness T4 of the fourth sub patterns 152 may be thicker than a thickness T3 of the third sub patterns 151. A lower surface of the lowest layer of the third sub patterns 151 may contact an upper surface of the seed pattern 140.

According to the embodiment of the inventive concepts that is described with reference to FIG. 2, the first pattern 150 may have a first thickness T1. However, according to an alternative embodiment of the inventive concepts, as described with reference to FIG. 6, the first pattern 150 may have a second thickness T2 and the second thickness T2 may be thicker than the first thickness T1. By repeatedly stacking the third sub patterns 151 and the fourth sub patterns 152, the first pattern 150 may have an easy axis that is substantially perpendicular to the upper surface of the substrate 100.

According to the inventive concepts, since the first pattern 150 includes an amorphous magnetic substance, the seed pattern 140 may not significantly affect the first pattern 150. That is, as described above, the transition of the surface roughness of the seed pattern 140 to the first vertical magnetic pattern 180 and the tunnel barrier pattern 190 through the first pattern 150 may be substantially prevented due to the characteristics provided by the amorphous material. Since the dispersion of the coercive force Hc of the first pattern 150 may thereby be decreased, the switching failure characteristics of a magnetic memory device may be improved. Moreover, as the surface roughness of the tunnel barrier pattern 190 decreases, a BV characteristic is improved and a magnetic memory device having excellent reliability may be obtained.

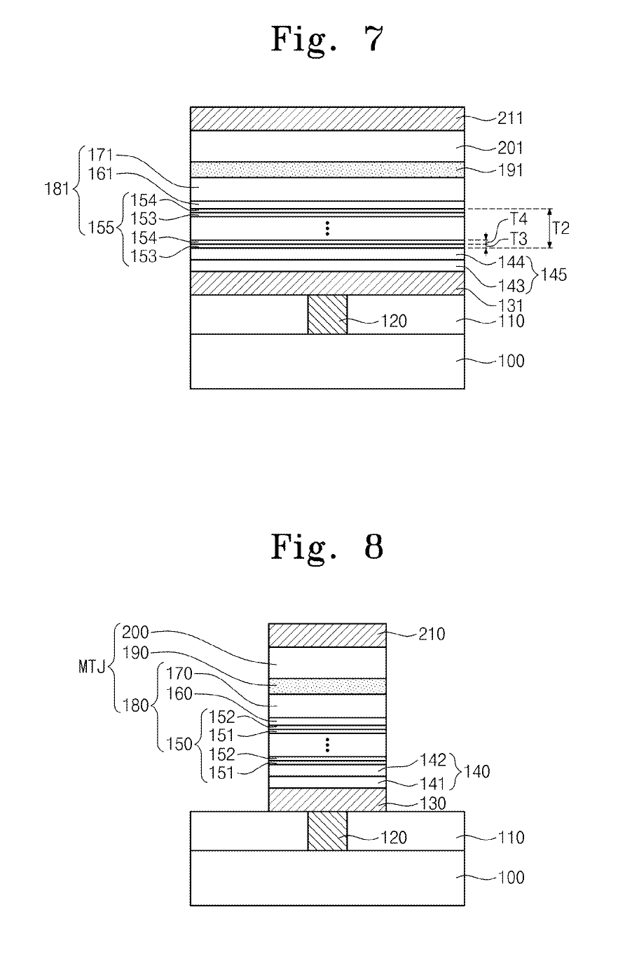

FIGS. 7 and 8 are schematic cross-sectional views of a partially constructed magnetic memory device for explaining a method of manufacturing a magnetic memory device according to an embodiment of the inventive concepts. The same reference numerals are used designate similar elements to those in FIGS. 3 and 5, and duplicate descriptions thereof may be omitted for simplicity.

Referring to FIG. 7, the first layer 155 may be formed on the seed layer 145 as described previously with reference to FIG. 3. The first layer 155 may be a multi-layer structure formed by alternately and repeatedly stacking a third sub layer 153 and a fourth sub layer 154. The third sub layer 153 may include an amorphous magnetic substance. For example, the amorphous magnetic substance may include at least one of CoB, FeB, CoFeB, CoFeBTa, CoFeSiB, FeZr, and CoHf. The fourth sub layer 154 may include at least one of platinum (Pt), palladium (Pd), and nickel (Ni). The first layer 155 may, for instance, be formed with a structure of (CoB/Pt)n (where n represents the number of stacked structures). A thickness T4 of the fourth sub layer 154 may be formed to be thicker than a thickness T3 of the third sub layer 153. The first layer 155 may be formed, for example, using a sputtering process and may be formed to have a second thickness T2. The second thickness T2 may be thicker than the first thickness T1 of the first layer 155 described with reference to FIG. 4.

Referring to FIG. 8, the second conductive layer 211, the second vertical magnetic layer 201, the tunnel barrier layer 191, the first vertical magnetic layer 181, the seed layer 145, and the first conductive layer 131 are successively patterned to produce a stacked, multi-layer structure including a first conductive pattern 130, a seed pattern 140, a first vertical magnetic pattern 180, a tunnel barrier pattern 190, a second vertical magnetic pattern 200, and a second conductive pattern 210. The seed pattern 140 may include a sequentially stacked first and second sub patterns 141 and 142. The first vertical magnetic pattern 180 may include the sequentially stacked a first pattern 150, an exchange coupling pattern 160, and a second pattern 170. The first pattern 150 may be formed as a multi-layered structure in which third and fourth sub patterns 151 and 152 are alternately and repeatedly stacked.

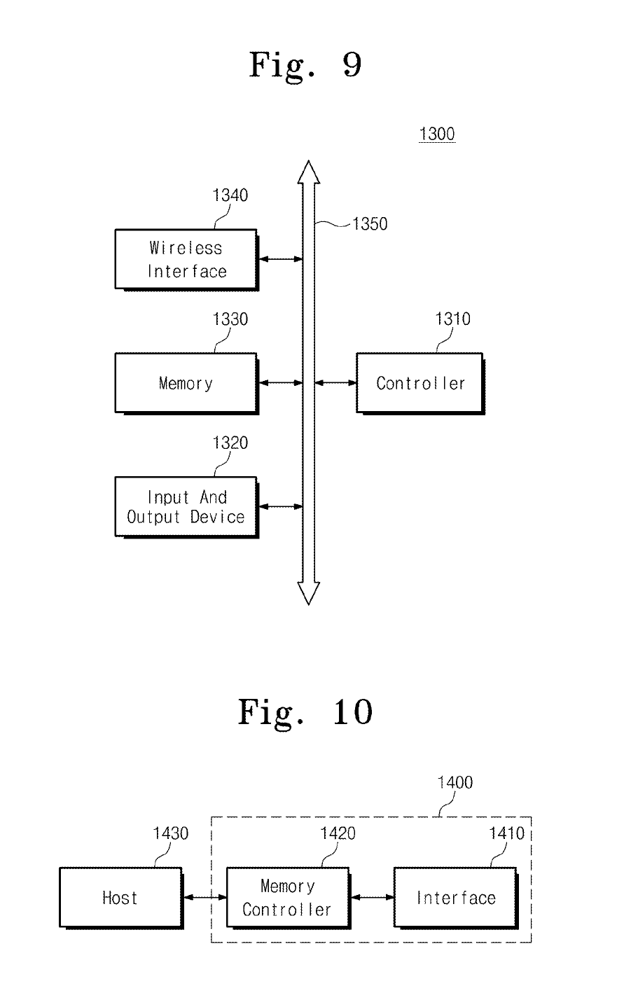

FIGS. 9 and 10 are schematic block diagrams illustrating electronic devices that may include a semiconductor device constructed according to embodiments of the inventive concepts. Referring to FIG. 9, an electronic device 1300 that includes a semiconductor device constructed according to embodiments of the inventive concepts may be one of a PDA, a laptop computer, a portable computer, a web tablet, a wireless phone, a cellular phone, a digital music player, wired/wireless electronic equipment and a composite electronic device including at least two thereof. The electronic device 1300 may include a controller 1310, a key pad, a keyboard, an input and output display 1320 such as a display, a memory 1330, and a wireless interface 1340 that are coupled to each other through a bus 1350. The controller 1310 may include, for example, one or more microprocessors, a digital signal processor, a micro controller, or the like. The memory 1330 may be used for storing, for example, commands that are executed by the controller 1310. The memory 1330 may be used for storing user data and include the semiconductor device according to the above-described embodiments of the inventive concepts. The electronic device 1300 may use the wireless interface 1340 to transmit data to a wireless communication network communicating by using RF signals or to receive data from the network. For example, the wireless interface 1340 may include an antenna, a wireless transceiver, etc. The electronic device 1300 may be used for implementing a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, etc.

Referring to FIG. 10, semiconductor devices constructed according to embodiments of the inventive concepts may be used for implementing a memory system. The memory system 1400 may include a memory device 1410 for storing massive data and a memory controller 1420. The memory controller 1420 controls the memory device 1410 so that data is read/written from/to the memory device in response to a read/write request from a host 1430. The memory controller 1420 may configure an address mapping table for mapping an address provided from the host 1430 such as mobile equipment or a computer system to a physical address of the memory device 1410. The memory device 1410 may include a semiconductor device according to the above-described embodiments of the inventive concepts.

The semiconductor devices that are disclosed in the above-described embodiments may be implemented as semiconductor packages of various types. For example, the semiconductor devices according to the embodiments of the inventive concepts may be packaged by Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (PMQFP), Thin Quad Flat Pack (TQFP), Small Out line (SOIC), Shrink Small Outline Package (SSOP), Thin Small Out line (TSOP), Thin Quad Flat Pack (TQFP), System In Package (SIP), Multi Chip Package (MCP), Wafer-level Fabricated Package (WFP), or Wafer-Level Processed Stack Package (WSP) method.

The package on which the semiconductor device according to the embodiments of the inventive concepts is mounted may further include a controller and/or a logic device that controls the semiconductor device.

According to the inventive concepts, the switching failure and BV characteristic of a magnetic memory device may be improved. Thus, a magnetic memory device having excellent reliability and a method of manufacturing the same may be provided.

The foregoing description of the embodiments of the inventive concepts provides exemplary examples of the inventive concepts. Thus, the inventive concepts are not limited to the foregoing embodiments, and it will be obvious to those skilled in the art that numerous modifications and alterations may be made to the embodiments described herein without departing from the spirit and scope of the inventive concepts.

What is claimed is:

1. A magnetic memory device comprising:
a first vertical magnetic pattern on a substrate;
a second vertical magnetic pattern on the first vertical magnetic pattern; and
a tunnel barrier pattern between the first vertical magnetic pattern and the second vertical magnetic pattern, and
wherein the first vertical magnetic pattern comprises:
a first pattern on the substrate;
a second pattern on the first pattern; and
an exchange coupling pattern disposed between the first pattern and the second pattern,
wherein the first pattern comprises an amorphous magnetic substance and a component X, wherein the component X comprises at least one of platinum, palladium, and nickel.

2. The magnetic memory device of claim 1, wherein the first pattern has a super lattice structure that is formed by alternately stacking the amorphous magnetic substance and the component X.

3. The magnetic memory device of claim 1, wherein the amorphous magnetic substance comprises at least one of CoB, FeB, CoFeB, CoFeBTa, CoFeSiB, FeZr, and CoHf.

4. The magnetic memory device of claim 1, further comprising a seed pattern disposed between the substrate and the first pattern, wherein a lower surface of the first pattern contacts an upper surface of the seed pattern.

5. The magnetic memory device of claim 4, wherein the seed pattern comprises ruthenium (Ru).

6. The magnetic memory device of claim 1, wherein the first pattern comprises first sub patterns and second sub patterns, wherein the first sub patterns comprise the amorphous magnetic substance; and wherein the second sub patterns comprise the component X, and
wherein the first pattern has a multi-layered structure in which the first sub patterns and the second sub patterns are alternately stacked n number of times, where n is an integer greater than 1.

7. The magnetic memory device of claim 6, further comprising a seed pattern disposed between the substrate and the first pattern, and
wherein a lower surface of a lowest layer of the first sub patterns contacts an upper surface of the seed pattern.

8. The magnetic memory device of claim 6, wherein a thickness of each of the second sub patterns is thicker than a thickness of each of the first sub patterns.

9. The magnetic memory device of claim 1, wherein the first vertical magnetic pattern is a pinned layer having a fixed magnetization direction.

10. The magnetic memory device of claim 9, wherein the first pattern has a magnetization direction that is uni-directionally fixed in a direction substantially perpendicular to an upper surface of the substrate, and
wherein the second pattern has a magnetization direction that is substantially perpendicular to an upper surface of the substrate and is fixed to be anti-parallel to the magnetization direction of the first pattern.

11. The magnetic memory device of claim 1, wherein the second vertical magnetic pattern is a free layer having a variable magnetization direction.

12. A method of manufacturing a magnetic memory device, the method comprising:
forming a seed layer on a substrate;
alternately and repeatedly depositing an amorphous magnetic substance and a component X on the seed layer to form a first layer;
forming an exchange coupling layer on the first layer;
forming a second layer on the exchange coupling layer; and
successively patterning the second layer, the exchange coupling layer, the first layer, and the seed layer to form a seed pattern, a first pattern, an exchange coupling pattern, and a second pattern that are sequentially stacked on the substrate,
wherein the component X comprises at least one of platinum, palladium, and nickel.

13. The method of claim 12, wherein the amorphous magnetic substance comprises at least one of CoB, FeB, CoFeB, CoFeBTa, CoFeSiB, FeZr, and CoHf.

14. The method of claim 12, wherein the first pattern has a magnetization direction that is substantially perpendicular to an upper surface of the substrate and that is uni-directionally fixed, and
wherein the second pattern has a magnetization direction that is substantially perpendicular to an upper surface of the substrate and that is fixed to be anti-parallel to the magnetization direction of the first pattern.

15. The method of claim 12, wherein the first layer is formed as a super lattice structure in which the amorphous magnetic substance and the component X are alternately stacked, and
wherein the depositing is performed at a temperature of between about 300° C. to about 350° C. using a high-temperature sputtering process.

16. A magnetic memory element comprising:
a substrate;
a pinned layer formed on the substrate and having a fixed magnetization direction that is substantially perpendicular to an upper surface of the substrate;
a free layer formed on the pinned layer and having a variable magnetization direction that is substantially perpendicular to an upper surface of the substrate; and
a tunnel barrier pattern disposed between the pinned layer and the free layer;
wherein the pinned layer comprises:
a first pattern arranged on the substrate, said first pattern comprising a multi-layer structure comprising stacked layers of an amorphous magnetic substance and a component comprising at least one of platinum, palladium, and nickel;
a second pattern arranged on the first pattern; and
an exchange coupling pattern disposed between the first pattern and the second pattern.

17. The magnetic memory element of claim 16, wherein the amorphous magnetic substance comprises at least one of CoB, FeB, CoFeB, CoFeBTa, CoFeSiB, FeZr, and CoHf.

18. The magnetic memory element of claim 16, further comprising a seed pattern disposed between the substrate and the first pattern, wherein a lower surface of the first pattern contacts an upper surface of the seed pattern.

19. The magnetic memory element of claim 16, wherein the first pattern comprises first sub patterns and second sub patterns, wherein the first sub patterns comprise the amorphous magnetic substance; and wherein the second sub patterns comprise the component, and
wherein the first pattern has a multi-layered structure in which the first sub patterns and the second sub patterns are alternately stacked n number of times, where n is an integer greater than 1.

20. The magnetic memory element of claim 19, wherein a thickness of each of the second sub patterns is thicker than a thickness of each of the first sub patterns.
